(19) United States
(12) Patent Application Publication
(10) Pub. No.: US 2004/0159925 A1
(43) Pub. Date: Aug. 19, 2004

(54) Semiconductor device and method for manufacture thereof

(75) Inventors: Tetsuya Matsuura, Tokyo (JP); Kazunari Michii, Tokyo (JP); Jun Shibata, Tokyo (JP); Koji Bando, Tokyo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/628,461

(22) Filed: Jul. 29, 2003

(30) Foreign Application Priority Data
Feb. 19, 2003 (JP) 2003-040787

(51) Int. Cl. H01L 23/02

(52) U.S. Cl. 257/678

(57) ABSTRACT

In a semiconductor device, a first semiconductor including a substrate, and a semiconductor chip disposed on the major surface of the substrate and sealed with a resin; a wiring board; spacers disposed between the wiring board and the substrate; and a second semiconductor. At this time, the second semiconductor is electrically connected to the wiring board and disposed in the space formed by the wiring board, the substrate, and the spacer. The spacer is disposed so as to the first semiconductor to the wiring board electrically.

### BACKGROUND OF THE INVENTION

1. Field of the Invention

The present invention relates to a semiconductor device and a method for manufacturing the semiconductor device. Specifically, the present invention relates to a semiconductor device having a plurality of semiconductor chips in a device, and a method for manufacturing such a semiconductor device.

2. Background Art

With recent increase in demands for the size reduction and the performance improvement of electronic appliances, demands for the size reduction and the performance improvement of semiconductor devices built in electronic appliances have also increased. In response to such demands, various means for the size reduction and the performance improvement of semiconductor devices have been studied. As one of these means, a method for mounting a plurality of semiconductors in piles in a semiconductor device package has been considered.

Methods for mounting a plurality of semiconductors in piles in a semiconductor device package include a method wherein, for example, a concave portion is formed on the back side of a substrate for mounting semiconductors for the upper level, and in the space of the concave portion, semiconductors for the lower level are accommodated. (For example, refer to Japanese Patent Application Laid-Open 11-112121.)

However, when a semiconductor device of such a structure is manufactured, counter boring for forming the concave portion must be performed on the substrate of semiconductors to be disposed on the upper level. Therefore, time and costs are consumed for the manufacture of the substrate itself, which accordingly leads to increase in the manufacturing time and manufacturing costs of the entire semiconductor device.

### SUMMARY OF THE INVENTION

Therefore, aiming at the solution of the above-described problems, the present invention proposes a semiconductor device using a package that can lead to the size reduction and the performance improvement of semiconductor devices while minimizing the manufacturing time and manufacturing costs of the semiconductor device.

According to one aspect of the present invention, a semiconductor device comprises a first semiconductor including a substrate, and a semiconductor chip disposed on the major surface of the substrate and sealed with a resin; a wiring board, spacers disposed between the wiring board and the substrate and a second semiconductor. At this time, the second semiconductor is electrically connected to the wiring board and disposed in the space formed by the wiring board, the substrate, and the spacer. The spacer connects the first semiconductor to the wiring board electrically.

According to another aspect of the present invention, in a method for manufacturing a semiconductor device, a first semiconductor is mounted on the respective spacers of a spacer substrate formed by the sequence of a plurality of spacers for a semiconductor device. A second semiconductor is mounted on the opposite sides of the portions of the respective spacers whereon the first spacer has been connected, and in the same direction of the first semiconductor, respectivel. The spacer substrate is split for each of the semiconductor devices.

Other and further objects, features and advantages of the invention will appear more fully from the following description.

### BRIEF DESCRIPTION OF THE DRAWINGS

FIG. 1 is a sectional view for illustrating a semiconductor device 100 in the first embodiment of the present invention;

FIG. 2 is a back view that contains a partially perspective view for illustrating the semiconductor device 100;

FIG. 3 is a schematic diagram of a cross section of a spacer 400 in the A-A′ direction in FIG. 2;

FIG. 4 is a sectional view for illustrating another semiconductor device in the first embodiment of the present invention;

FIG. 5 is a top view for illustrating a spacer substrate 420 in the second embodiment of the present invention;

FIG. 6 is a sectional view of the spacer substrate 420 in the B-B′ direction in FIG. 5

FIG. 7 is a flow diagram for illustrating the method for manufacturing a semiconductor device 100 in the second embodiment of the present invention;

FIGS. 8 to 12 are sectional views for illustrating the states in each manufacturing step of the semiconductor device 100 in the second embodiment.

FIG. 13 is a sectional view for illustrating a semiconductor device 500 of the present invention.

### DETAILED DESCRIPTION OF THE PREFERRED EMBODIMENTS

The embodiments of the present invention will be described below referring to the drawings. In the drawings, the same or like parts will be denoted by the same reference numerals, and the description thereof will be simplified or omitted.

### First Embodiment

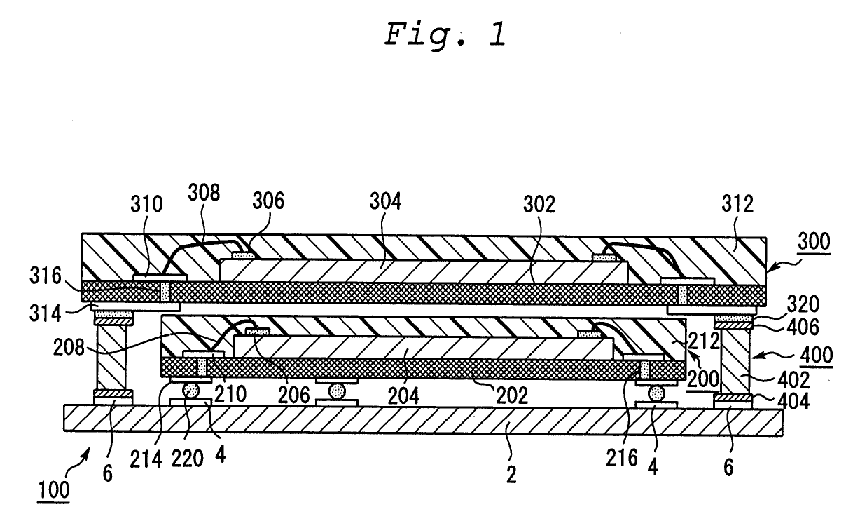

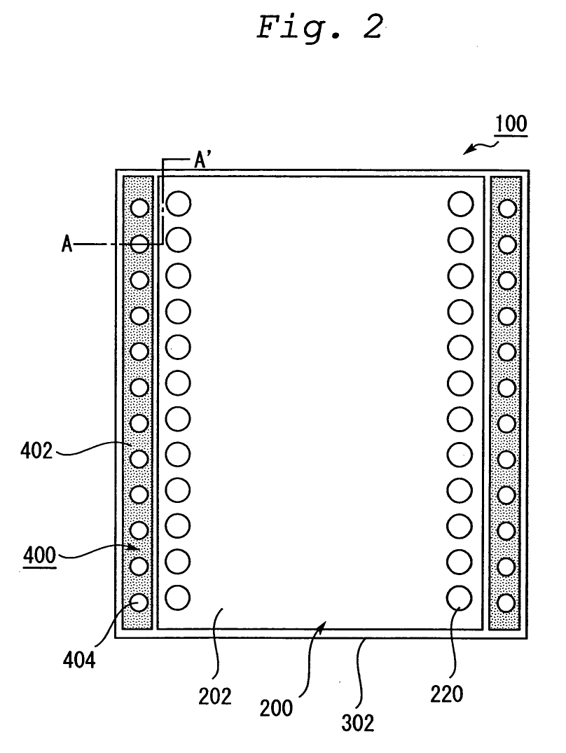

FIG. 1 is a sectional view for illustrating a semiconductor device 100 in the first embodiment of the present invention. FIG. 2 is a back view that contains a partially perspective view for illustrating the semiconductor device 100.

Referring to FIG. 1, in the semiconductor device 100, lower-level semiconductor 200 is disposed on a wiring board 2, and an upper-level semiconductor 300 is disposed. The upper-level semiconductor 300 is disposed on the wiring board 2 with a predetermined distance using spacers 400, and lower-level semiconductor 200 are disposed in the space surrounded by the wiring board 2, spacers 400, and the upper-level semiconductor 300. In FIG. 2, however, the perspective state of the wiring board 2 is shown.

The specific structure of the semiconductor device 100 will be described referring to the drawings. In this specification, the upper side in FIG. 1 is called the major-surface side of respective parts of the semiconductor device 100, and the side facing the major-surface side (i.e., the lower side in FIG. 1) is called the backside.

On the wiring board 2, a plurality of lands 4 for the lower-level semiconductors 200 and a plurality of lands 6 for the upper-level semiconductor 300 are disposed. Two rows of the predetermined number of the lands 4 for the lower-level semiconductors 200 are arranged in parallel in the vertical direction to the page in FIG. 1. Two rows of the predetermined number of the lands 6 for the upper-level semiconductor 300 are arranged in parallel outside the rows of lands 4 in the depth direction. Each of lands 4 and 6 are connected to terminals (not shown) that can be connected to external electrodes to enable electrical connection to external devices.

In the lower-level semiconductor 200, a semiconductor chip 204 is disposed on the major surface of the substrate 202. On the major surface of the semiconductor chip 204, a plurality of bonding pads 206 are arranged in two rows along two sided facing each other in parallel to the depth direction of the major surface of the semiconductor chip 204. To each bonding pad 206, an end of each of wires 208 is connected. Outside of the semiconductor chip 204 of the substrate 202, a plurality of pads 210 are arranged in two rows in the depth direction corresponding to each of bonding pads 206. The other end of each wire 208 in connected to each of the pads 210. In the state wherein each bonding pad 206 is thus connected to a pad 210 through a wire 208, the semiconductor chip 204 is sealed with an insulating resin 212 on the major surface of the substrate 202.

On the other hand, referring to FIG. 13, a plurality of lands 214 are arranged in two rows on the locations corresponding to each pad 210, that is, along two sided facing each other parallel to the depth direction of the substrate 202. Each pad 210 is connected to each land 214 through each of through holes 216 formed in the substrate 202. The through holes 216 are filled with a conductor, and thereby the electrical connection of each pad 210 to each land 214 is enabled. Each of solder balls 220 is provided to each land 214. The solder balls 220 are connected to the lands 4 for the lower-level semiconductor 200 disposed on the wiring board 2.

In the lower-level semiconductor 200, each bonding pad 206 of the semiconductor chip 204 is thus connected to a pad 210 through a wire 208. Each pad 210 is also connected to a land 214 through a through hole 216. Furthermore, each land 214 is connected to a land 4 on the wiring board 2 through a solder ball 220. Thus, the electrical connection of the semiconductor chip 204 to external devices is enabled.

The upper-level semiconductor 300 is also constituted in substantially the same way as the lower-level semiconductor 200. Specifically, the upper-level semiconductor 300, in the state wherein a semiconductor chip 304 is disposed on a substrate 302, and bonding pads 306 on the major surface thereof are connected to pads 306 with wires 308, is sealed on the major surface of the substrate 302 with a sealing resin 312. Each pad 310 is also connected to each of lands 314 through each of through holes 316.

However, unlike the lower-level semiconductor 200, the lands 314 of the upper-level semiconductor 300 are not provided with solder balls 220. In place of solder balls, the lands 314 are provided with solder paste 320, whereby the lands 314 are connected to the predetermined locations of spacers 400.

Spacers 400 have spacer members 402. As FIG. 2 shows, two spacer members 402 are disposed along two sides facing each other in parallel to the depth direction on the major surface of the wiring board 2. In the cross section shown in FIG. 1, each spacer member 402 is a prism member of a height somewhat higher than the lower-level semiconductor 200. Again referring to FIG. 2, when viewed from the back, each spacer member 402 is a rod-like member extending to the depth direction.

A plurality of lower-level lands 404 are arranged in a row in the depth direction on the back face each apace member 402. Referring to FIG. 1, on the major surface side of each spacer member 402, the same number of upper-level lands 406 are arranged corresponding to each of lower-level lands 404.

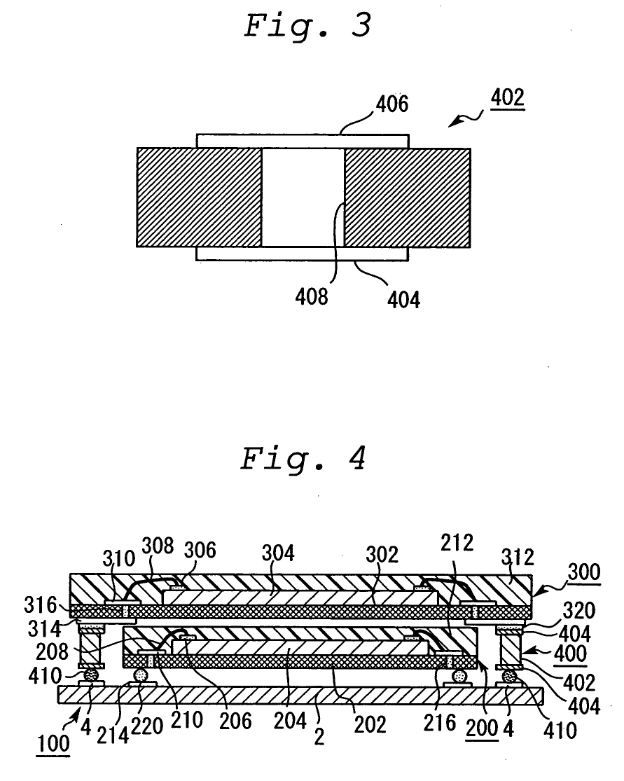

FIG. 3 is a schematic diagram of a cross section of a spacer 400 in the A-A′ direction in FIG. 2.

As FIG. 3 shows, in the location inside each spacer member 402 where lands 404 and 406 are provided, a through hole 408 that passes through the spacer member 402 from the major surface side to the back face side is formed. Each through hole 408 is filled with a conductor, whereby the each of lower-level lands 404 is connected to each of upper-level lands 406.

The lower-level lands 404 of each spacer member 402 thus constituted in connected to each of lands 6 for the upper-level semiconductor 300 of the wiring board 2. Each of the upper-level lands 406 of each spacer member 402 is also connected to a land 314 on the back face of the upper-level semiconductor 300.

Specifically, in the upper-level semiconductor 300, each bonding pad 306 formed on the major surface of the semiconductor chip 304 is connected to each of pads 310 through a wire 308, and each pad 310 is connected to a land 314 through a through hole 316. Each land 314 is connected to each of upper-level lands 406 through solder paste 320, and each upper-level land 406 is connected to each of lower-level lands 404 through a through hole 408. Furthermore, each lower-level land 404 is connected to each of lands 6 for the upper-level semiconductor 300 on the major surface of the wiring board 2, whereby the semiconductor chip 304 can be electrically connected to external devices.

The lower-level semiconductor 200 is disposed in a space formed between the substrate 302 of the upper-level semiconductor 300 and the wiring board 2 through spacers 400 in the state wherein contact to the external devices is secured.

Since the semiconductor device 100 is constituted as described above, each terminal for connection provided on each member, that is, lands 4 and 6 of the wiring board 2; solder balls 220, lands 214, pads 210, and bonding pads 206 of the lower-level semiconductor 200; lands 314, pads 310, and bonding pads 306 of the semiconductor 300; and lands 404 and 406 of the spacers 400 are arranged on the predetermined locations along two sides parallel to the depth direction facing each other of the wiring board 2, the substrate 202, or the substrate 302, and are disposed on the locations corresponding to each terminal connected to each other, in the same number as the number of the corresponding terminals.

According to the present invention, as described above, an upper-level semiconductor 300 can be disposed on spacers 400; and a lower-level semiconductor 200 can be disposed in a space surrounded by the upper-level semiconductor 300 and the spacers 400. Therefore, two semiconductors can be mounted in one semiconductor device 100, and the size reduction and performance improvement of a semiconductor device can be achieved. Also, the upper-level semiconductor 300 and the lower-level semiconductor 200 can be formed in usual processes, and these semiconductors can be piled using spacers 400 in the packaged state using a conventional package. Therefore, if only spacers 400 are prepared, a smaller and higher-performance semiconductor device can be obtained in low costs without preparing special members, such as a substrate for mounting upper- and lower-level semiconductors, and without complicated processes.

In the first embodiment, the case wherein bonding pads 206 and 306 in the semiconductors 200 and 300 are arranged only on the two facing sides of the circumferential portion of the semiconductor chips 204 and 304, respectively, and the terminals of respective members are formed corresponding to this was described. However, the present invention is not limited to such an arrangement of terminals, but, other structures, such as a structure wherein bonding pads are arranged on all circumferential portions may also be used. Such a case may be dealt with by providing spacers having lands to meet the locations of the lands of the upper-level semiconductor disposed corresponding to the arrangement of the bonding pads.

In the present invention, the package of upper- and lower-level semiconductors is not limited to the package of the lower-level semiconductor 200 and the upper-level semiconductor 300 described in the first embodiment. For example, the bonding pads are not connected to the pads on the substrate with wires, but the package may have other structures, such as the structure wherein upper and lower-level semiconductors are directly connected through the through holes formed in the substrate. In this case also, the spacers having lands so as to connect to the terminals for connecting to external devices provided on the substrate of the upper-level semiconductor may be used.

Also in the present invention, the case wherein the spacer members 402 use solder lands as the low-level lands 404, thereby connecting to the lands of the wiring board 2 was described. However, the present invention is not limited to this, but for example, as FIG. 4 shows, solder balls 410 may be used in the lower-level land portions 404, thereby connecting to the lands 6 of the wiring board 2. Also, this is not limiter to the lower-level lands 404, but the upper-level lands 406 or the solder paste 320 of the semiconductor 300 may be substituted by solder balls, or the solder balls 220 of the semiconductor 200 may be substituted by a solder paste or the like.

### Second Embodiment

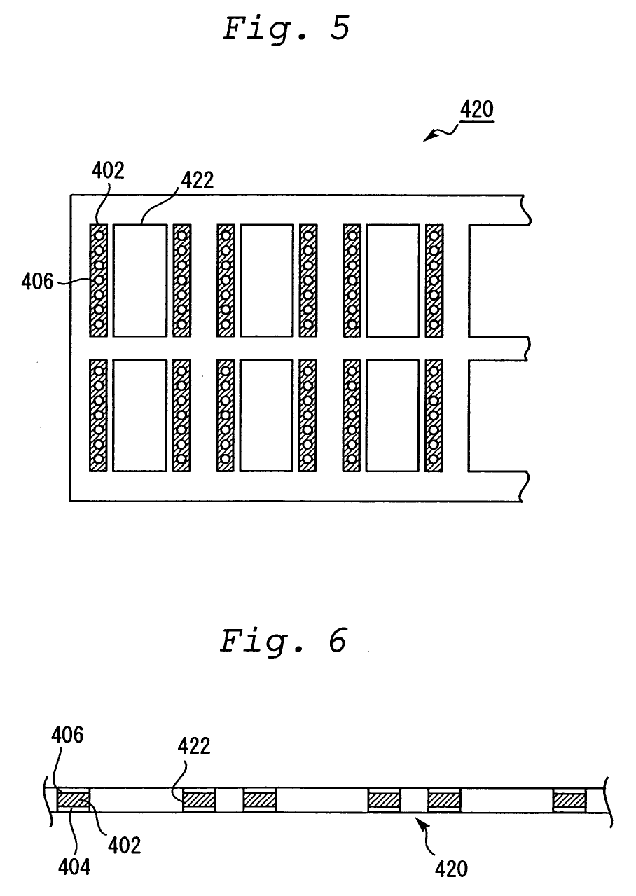

FIG. 5 is a top view for illustrating a spacer substrate 420 in the second embodiment of the present invention. FIG. 6 is a sectional view of the spacer substrate 420 in the B-B′ direction in FIG. 5.

The semiconductor device 100 manufactured in the second embodiment is the similar to the semiconductor device manufactured in the first embodiment. Therefore, the spacers 400 used in the semiconductor device 100 similarly comprise spacer members 402, and lower-level lands 404 and upper-level lands 406 connected by through holes 408.

However, in the second embodiment, the semiconductor device 100 is assembled using a spacer substrate 420 as shown in FIGS. 5 and 6. As FIGS. 5 and 6 show, a plurality of sets of spacer members 402 used in one semiconductor device 100 are formed sequentially on the spacer substrate 420. In the portions sandwiched by the sets of spacer members 402, spaces 422 for mounting the lower-level semiconductor 200 are formed. The spacer members 402 have previously formed lower-level lands 404 and upper-level lands 406 connected by through holes 408 ad described in the first embodiment.

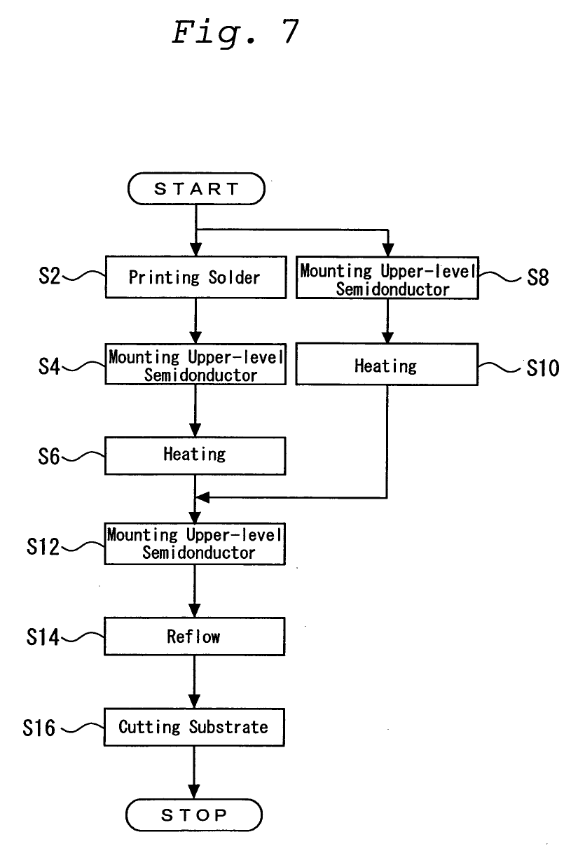

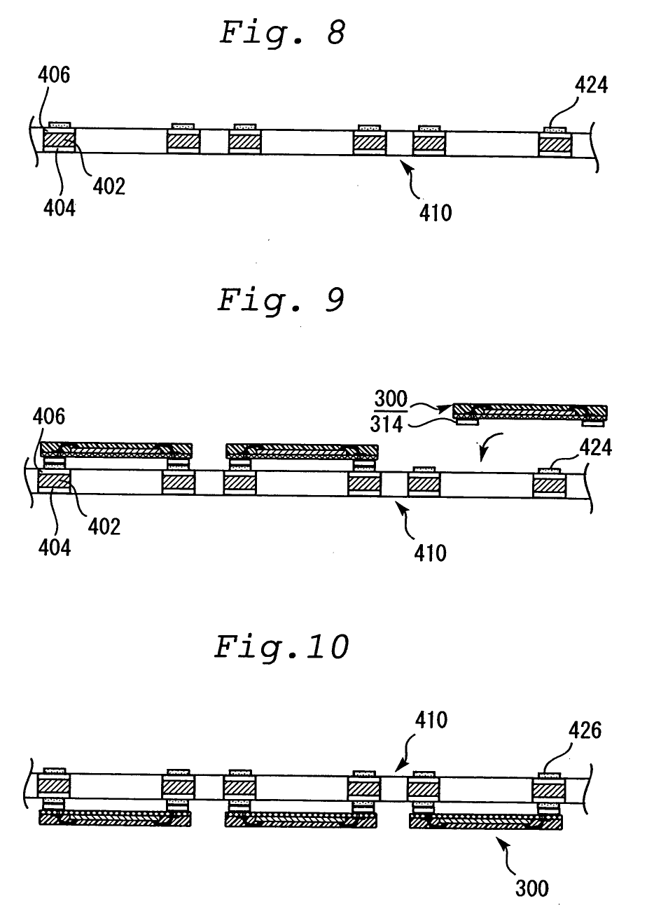

FIG. 7 is a flow diagram for illustrating the method for manufacturing a semiconductor device 100 in the second embodiment of the present invention. FIGS. 8 to 12 are sectional views for illustrating the states in each manufacturing step of the semiconductor device 100 in the second embodiment.

Referring to FIGS. 7 to 12, the method for manufacturing the semiconductor device 100 in the second embodiment of the present invention will be described below.

First, as FIG. 8 shows, solder 424 is printed on the upper-level lands 406 of the spacer substrate 420 (Step S2). Next, as FIG. 9 shows, through solder 424, the upper-level semiconductors 300 are placed on the spacer members 402 (Step S4), and heated (Step S6). Thereby, the solder 424 is melted to bond the upper lands 406 to the lands 314 of the upper-level semiconductors 300. Then, as FIG. 10 shows, solder 426 is printed on the lower-level lands 404 of the spacer substrate 420.

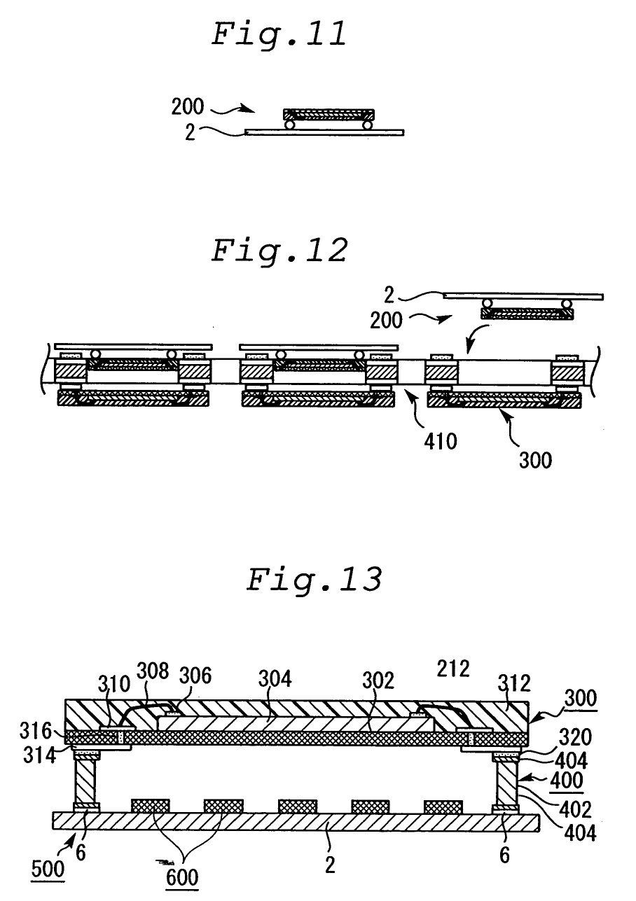

On the other hand, as FIG. 11 shows, lower-level semiconductors 200 are mounted on wiring boards 2 (Step S8), and heated (step S10). Thereby, the lower-level semiconductors 200 are bonded to the wiring boards 2.

Next, as FIG. 12 shows, through solder 426, the lower-level semiconductors 200 are placed on the lower-level lands 404 of the spacer substrate 420 (Step S12). This must be done so that the lower-level semiconductors 200 are disposed in the spaces 422 of the spacer substrate 420. Thereafter, reflow is performed (Step S14), and the spacer substrate 420 is cut into individual semiconductors 100 (Step S16).

As described above, the semiconductor device 100 as shown in FIG. 1 is formed.

Since other portions are identical as the first embodiment, the description thereof will be omitted.

According to the second embodiment, as described above, a spacer substrate 420 whereon a plurality of spacers 400 are sequentially formed is used. Thereby, the step for mounting upper-level semiconductors 300 and lower-level semiconductors 200 can be collectively performed for a plurality of semiconductor devices, and the time consumed in manufacturing semiconductor devices can be reduced.

In this embodiment, the case wherein upper- and lower-level semiconductors 200 and 300 are mounted only on the major surface side of the wiring board 2 was described. However, the present invention is not limited thereto, but semiconductors 200 and 300 may be mounted on both surfaces of the wiring board 2. In this case also, the semiconductor device can be assembled by repeating similar steps as described above.

### Third Embodiment

FIG. 13 is a sectional view for illustrating a semiconductor device 500 of the present invention.

As FIG. 13 shows, the constitution of the upper-level semiconductors 300 and spacers 400 of the semiconductor device 500 is similar to the semiconductor device 100 described in the first embodiment. In the semiconductor device 500, however, the lower-level semiconductors 600 disposed under the upper-level semiconductors 300 differ from what were described in the first embodiment. Although the lower-level semiconductor 200 described in the first embodiment is packaged using BGA (Ball Grid Array), the lower-level semiconductors 600 are small semiconductors packaged using LGA (Land Grid Array). Five lower-level semiconductors 600 are disposed underneath the upper-level semiconductors 300, and are connected to lands 4 formed on the wiring board 2 correspondingly.

Since other portions are identical as the first embodiment, the description thereof will be omitted.

According to the third embodiment, ad described above, spacers are provided between the upper-level semiconductors 300 and the wiring board 2. Therefore, the lower-level semiconductors 600 can be disposed between the wiring board 2 and the upper-level semiconductors 300, and the size reduction and performance improvement of the semiconductor device 100 can be achieved.

Although five semiconductors are disposed as the lower-level semiconductors, the present invention is not limited thereto, but a required number of semiconductors can be disposed considering the space underneath the upper-level semiconductors 300 and the size of the lower-level semiconductors.

In this embodiment, a case wherein semiconductors are disposed using LGA was described. However, the present invention is not limited thereto, but semiconductors of other packages, such as QFP (Quad Flat Package), or chip components such as Trs and resistors may also be disposed.

The upper-level semiconductors 300 and the lower-level semiconductor 200 or 600 in the embodiments correspond, for example, to the first and second semiconductors in the present invention, respectively. The step for mounting the first semiconductor in the present invention is executed, for example, by executing Steps S2 to S6 in the second embodiment; the step for mounting the second semiconductor is executed, for example, by executing Steps S12; and the cutting step is executed, for example, by executing Steps S16.

The features and the advantages of the present invention as described above may be summarized as follows.

According to one aspect of the present invention, spacers are formed between a first semiconductor and a wiring board, and a second semiconductor is disposed in the space formed by the wiring board and the first semiconductor. Therefore, since semiconductors formed in ordinary steps can be easily piled without especially preparing substrates and the like for mounting first and second semiconductors, smaller and higher-performance semiconductor devices can be obtained in low costs.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2003-040787, filed on Feb. 19, 2003 including specification, claims, drawings and summary, on which the Convention priority of the present application is based, are incorporated herein by reference in its entirety.

1. A semiconductor device comprising
a first semiconductor comprising a substrate, and a semiconductor chip disposed on the major surface of said substrate and sealed with a resin;
a wiring board,
spacers disposed between said wiring board and said substrate and connecting said first semiconductor to said wiring board electrically; and
a second semiconductor electrically connected to said wiring board and disposed in the space formed by said wiring board, said substrate, and said spacer.

2. The semiconductor device according to claim 1, wherein a plurality of said semiconductors are disposed on said wiring board.

3. A method for manufacturing a semiconductor device comprising the steps of:
mounting a first semiconductor on the respective spacers of a spacer substrate formed by the sequence of a plurality of spacers for a semiconductor device;
mounting a second semiconductor on the opposite sides of the portions of said respective spacers whereon said first spacer has been connected, and in the same direction of said first semiconductor, respectively; and
splitting said spacer substrate for each of said semiconductor devices.
